(19) United States
(12) Patent Application Publication
(10) Pub. No.: US 2002/0177080 A1
(43) Pub. Date: Nov. 28, 2002

(54) Interconnects with dual dielectric spacers and method for forming the same

(76) Inventors: Cheng-Hui Chung, Hsinchu Hsien (TW); Yei-Hsiung Lin, Hsinchu (TW); Chen-Chiu Hsue, Hsinchu (TW)

Correspondence Address: BIRCH STEWART KOLASCH & BIRCH, PO BOX 747, FALLS CHURCH, VA, 22040-0747, US

(21) Appl. No.: 09/963,372

(22) Filed: Sep. 27, 2001

(30) Foreign Application Priority Data
May 23, 2001 (TW) 90112365

(51) Int. Cl. G03F 7/00

(52) U.S. Cl. 430/314; 430/311; 430/313; 430/317

(57) ABSTRACT

A method and a structure of interconnects with dual dielectric spacers is disclosed. A substrate with a plurality of interconnects is provided. A first dielectric layer is formed on the interconnects and the substrate. The first dielectric layer is partially etched back to expose a partial surface of the substrate and the top surface of the interconnects, leaving remaining first dielectric layers on the sides of the interconnects as first spacers. A second dielectric layer is formed on the interconnects, the first spacers and the substrate. The second dielectric layer is partially etched back to expose a partial surface of the substrate and the top surface of the interconnects, leaving remaining first spacers on the surface of the first spacers as second spacers. A third dielectric layer is formed on the substrate, the second spacers and the interconnects. Thus, the first spacers serve as stress buffer layers and the second spacers serve as etching stop layers and/or supporting layers of the interconnects.

### BACKGROUND OF THE INVENTION

1. Field of the Invention

The present invention relates to the semiconductor manufacturing process, and more particularly, to a method for forming interconnects with dual dielectric spacers and the structure thereof.

2. Description of the Related Art

In the traditional interconnect fabrication process of semiconductor manufacture, silicon oxide is usually used as an inter-metal dielectric (IMD) layer, formed on a metal layer/line. With increases in integration, misalignment often occurs during photolithography. This causes the inter-metal dielectric (IMD) layer to be over-etched, and causes current leakage to seriously affect device reliability. With the reduction of circuit size, the collapse of the thinner and weaker metal layer/line also occurs. This also seriously affects the device reliability.

To date, studies of misalignment in the interconnect process have only addressed the anti-refraction layer formed on the metal layer. For example, in U.S. Pat. No. 5,580,701, Lur et al disclosed forming an anti-reflection layer between the photoresist and its underlying poly layer. This eliminates the occurrence of standing wave between incident and reflected light. The method of U.S. Pat. No. 5,580,701 cannot, however, solve the problem mentioned previously.

FIGS. 1a˜1c are schematic views of a traditional interconnect process. FIG. 1a shows a structure of traditional interconnect. The structure comprises a semiconductor substrate 100 whereon a plurality of interconnects 110, 120 are formed, and a silicon oxide layer 130 is formed on the interconnects 110, 120 and the substrate 100, wherein the oxide layer 130 is used as an inter-metal dielectric layer.

In FIG. 1b, a via hole 140 is defined through the dielectric layer 130 to the interconnect 110, if misalignment occurs, over-etching will also occur. This causes the inter-metal dielectric layer 130 to be damaged, and causes the bottom of the via hole 140 to near the substrate 100, creating current leakage.

FIG. 1c shows how the shrinkage of metal lines can cause the collapse of the thinner and weaker interconnects. The foregoing disadvantages seriously affect device reliability and yield.

### SUMMARY OF THE INVENTION

It is therefore an object of the present invention to provide a method and a structure for interconnects with dual dielectric spacers.

To accomplish the above objective, the present invention provides a method of forming dual dielectric spacers on the sidewalls of interconnects. A substrate with a plurality of interconnects is provided. A conformal first dielectric layer is formed on the interconnects and the substrate. The first dielectric layer is partially etched back to form first spacers on the sidewalls of the interconnects, and to expose a partial surface of the substrate and the top surface of the interconnects. A conformal second dielectric layer is formed on the interconnects, the first spacers and the substrate. The second dielectric layer is partially etched back to form second spacers on the first spacers, and to expose a partial surface of the substrate and the top surface of the interconnects. A third dielectric layer is formed on the substrate, the second spacers and the interconnects. The third dielectric layer is performed by planarization, in which the first spacers serve as stress buffer layers and the second spacers serve as etching stop layers and/or supporting layers of the interconnects.

The structure of interconnects of the present invention is also provided. The structure comprises a substrate with a plurality of interconnects. First spacers formed on the sidewalls of the interconnects. Second spacers formed on the surface of the first spacers, in which the first spacers serve as stress buffer layers and the second spacers serve as etching stop layer and/or supporting layers of the interconnects.

The present invention improves on the prior art in that the interconnect structure has dual dielectric spacers, and the first spacers serve as stress buffer layers and the second spacers serve as etching stop layer and/or supporting layers of the interconnects. Thus, the invention can decrease current leakage when photolithography encounters misalignment, raises reliability and yield, achieves the goal of IC shrinkage, and ameliorates the disadvantages of prior art.

### BRIEF DESCRIPTION OF THE DRAWINGS

The present invention can be more fully understood by reading the subsequent detailed description in conjunction with the examples and references made of the accompanying drawings, wherein:

FIG. 1a is a schematic view of the interconnect structure of the prior art;

FIGS. 1b˜1c are schematic views of the interconnect structure of the prior art;

FIGS. 2˜8 are sectional diagrams of embodiments of the present invention;

FIG. 9 is a schematic view of embodiment of the present invention during misalignment occurs;

FIG. 10 is a sectional view of interconnects with dual dielectric spacers of the present invention;

### DETAILED DESCRIPTION OF THE PREFERRED EMBODIMENT

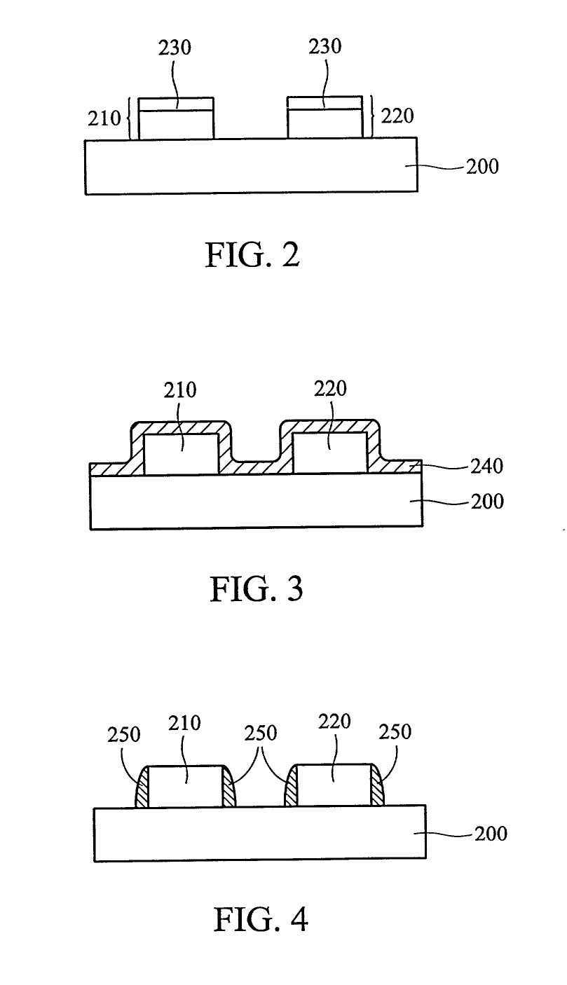

FIGS. 2˜8 are sectional diagrams of embodiments of the present invention.

FIG. 2 shows an embodiment of the present invention relating the formation of dual dielectric spacers on the sidewalls of interconnects. A plurality of interconnects 210, 220, are formed on a substrate 200. The interconnects 210, 220 may be, for example, Al, Cu, or AlSiCu alloy formed by deposition. At least one anti-reflection layer 230, such as Ti/TiN and SiON layer, is formed on the interconnects 210,220. The interconnects 210, 220 include the anti-reflection layer 230. In order to simplify the illustration, the anti-reflection layer 230 is not shown in FIGS. 3˜88.

FIG. 3 shows a conformal first dielectric layer 240 formed on the interconnects 210, 220 and the substrate 200. The first dielectric layer 240 may be, for example, silicon oxide formed by deposition, and the thickness of the first dielectric layer 240 is about 50˜300Å.

FIG. 4 shows the first dielectric layer 240 partially etched back to expose a partial surface of the substrate 200 and the top surface of the interconnects 210, 220. Moreover, the first dielectric layer 240 remains on the sidewalls of interconnects 210, 220, acting as first spacers 250. The first spacers 250 serve as stress buffer layers. The method of partial etching back may, for example, use CF₄ as gas plasma for dry etching.

In FIG. 5, a conformal second dielectric layer 260 is formed on the interconnects 210, 220, the first spacers 250 and the substrate 200. The second dielectric layer 260 may be an insulator layer formed by deposition, such as a silicon nitride layer or a silicon oxynitride layer. The thickness of the second dielectric layer 260 is between about 50˜300Å.

FIG. 6 shows the second dielectric layer 260 partially etched back to expose a partial surface of the substrate 200 and the top surface of the interconnects 210, 220. Moreover, the second dielectric layer 260 remains on the surface of the first spacers 250, acting as second spacers 270. The second spacers 270 serve as etching stop layers and/or supporting layers of the interconnects 210, 220. The method of partial etching back may, for example, use CF₄ or NF₃ as gas plasma for dry etching.

In FIG. 7, a third dielectric layer 280 is formed on the substrate 200, the second spacers 270 and the interconnects 210, 220. The third dielectric layer 280 may be, for example, a silicon oxide layer formed by deposition. The second spacers 270 serve as etching stop layers in the subsequent via etching process, and/or supporting layers of the interconnects 210, 220. The selective etching rate of the third dielectric layer 280 is greater than 10 times the selective etching rate of the second dielectric layer 270.

In FIG. 8, planarization is performed on the third dielectric layer 280 to smooth the surface of the third dielectric layer 280′. The planarization may be, for example, CMP or etching.

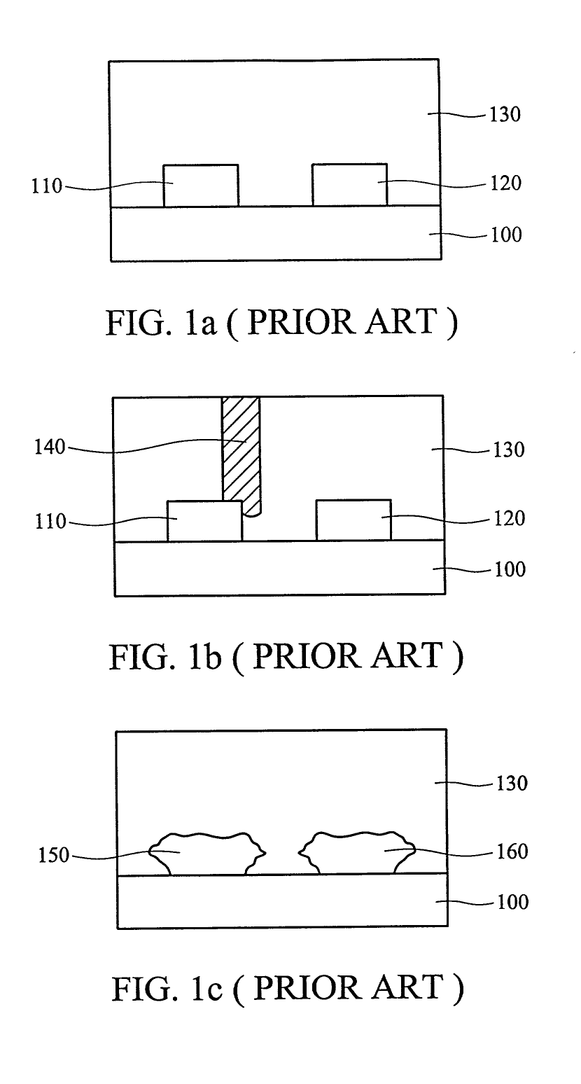

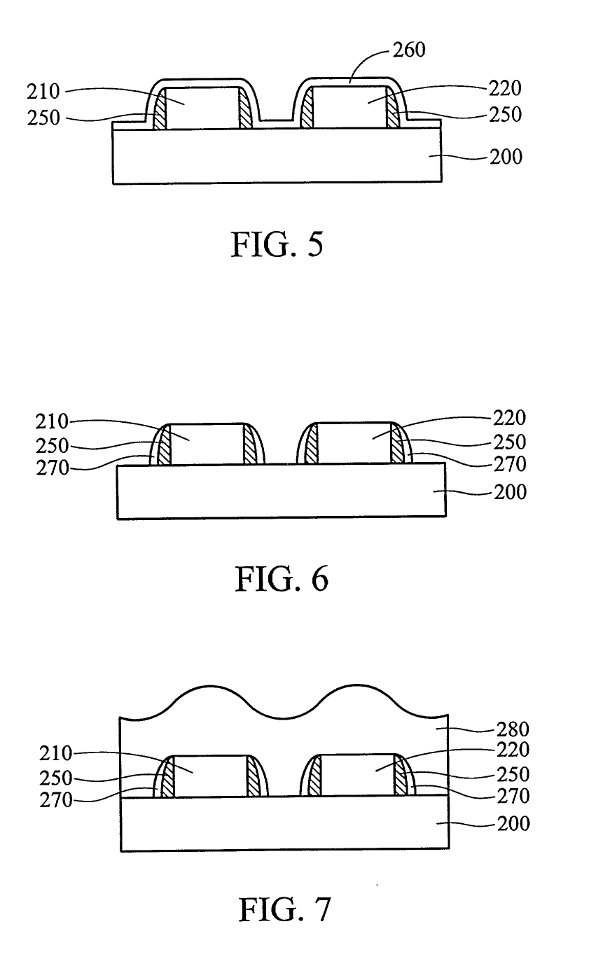

FIG. 9 is a schematic view of an embodiment of the present invention experiencing misalignment. When defining at least one via hole 290, if misalignment occurs, because the second spacers 270 of the present invention are used as etching stop layers, the via hole 290 will stop at the upper surface of the second spacer 270. The via hole 290 is not as shown in the FIG. 1b that damage the third dielectric layer 280′. Consequently, the present invention improves the reliability of product and enhances the endurance for misalignment of photolithography.

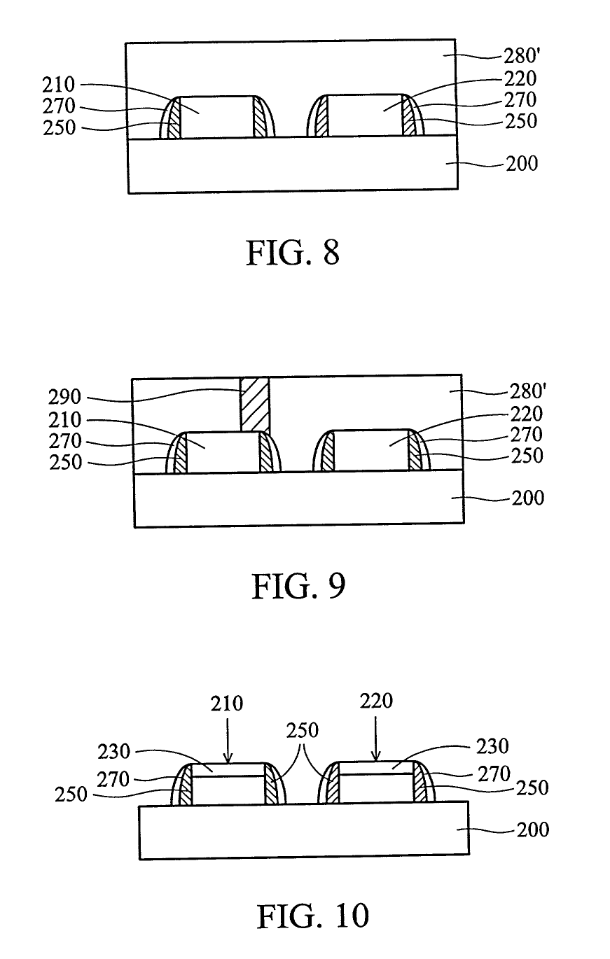

FIG. 10 shows a structure of interconnects with dual dielectric spacers. A substrate 200 is provided, having a plurality of interconnects 210,220. First spacers 250 are formed on the sidewalls of the interconnects 210, 220. Second spacers 270 are formed on the first spacers 250. The first spacers 250 serve as stress buffer layers and the second spacers 270 serve as etching stop layers and/or supporting layers of the interconnects 210, 220. The interconnects 210, 220 further include at least one anti-reflection layer 230. Interconnects 210,220 may be, for example, Al, Cu, or AlSiCu alloy. The anti-reflection layer 230 may be , for example, Ti/TiN or SiON. The first spacers 250 may be, for example, SiO₂. The second spacers 270 may be, for example, SiN or SiON.

Therefore, the present invention provides a method and a structure for interconnects with dual dielectric spacers. Since the interconnects 210, 220 have tensile stress, and the second spacer (SiN or SiON) 270 has compress stress, the inner spacers (the first spacers 250) can serve as stress buffer layers to release the stress between the interconnects and the second spacer, avoiding the occurrence of crack. The outer spacers (the second spacers 270) can serve as etching stop layers and/or supporting layers of the interconnects. Thus, the present invention significantly decreases current leakage and improves product reliability. Additionally, the present invention enhances resistance to the effects of misalignment, achieving the goal of IC shrinkage.

Finally, while the invention has been described by way of example and in terms of the above preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of manufacturing interconnects with dual dielectric spacers, comprising the steps of:
providing a substrate with a plurality of interconnects;
forming a conformal first dielectric layer on the interconnects and the substrate;
partial etching back of the first dielectric layer to expose a partial surface of the substrate and the top surface of the interconnects, leaving remaining first dielectric layers on the sidewalls of the interconnects, wherein the remaining first dielectric layers are first spacers;
forming a conformal second dielectric layer on the interconnects, the first spacers and the substrate;
partial etching back of the second dielectric layer to expose a partial surface of the substrate and the top surface of the interconnects, leaving remaining second layers on the surface of the first spacers, wherein the remaining second layers are second spacers;
forming a third dielectric layer on the substrate, the second spacers and the interconnects; and
performing planarization on the third dielectric layer using the first spacers as stress buffer layers and the second spacers as etching stop layers and supporting layers of the interconnects.

2. The method according to claim 1, wherein the etching rate of the third dielectric layer is greater than 10 times the etching rate of the second dielectric layer.

3. The method according to claim 1, wherein on the top of the interconnects, at least one further anti-reflection layer is formed.

4. The method according to claim 1, wherein the interconnects are selected from the group consisting of Al interconnects, Cu interconnects and AlSiCu alloy interconnects formed by deposition.

5. The method according to claim 1, wherein the first dielectric layer is a silicon oxide layer formed by deposition.

6. The method according to claim 1, wherein the second dielectric layer is selected from the group consisting of silicon nitride layer and silicon oxynitride layer formed by deposition.

7. The method according to claim 1, wherein the third dielectric layer is a silicon oxide layer formed by deposition.

8. The method according to claim 3, wherein the anti-reflection layer is selected from the group consisting of Ti/TiN layer and SiON layer formed by deposition.

9. A structure of interconnects with dual dielectric spacers, comprising:
a substrate with a plurality of interconnects;
first spacers formed on the sidewalls of the interconnects serving as stress buffer layers; and
second spacers formed on the surface of the first spacers serving as etching stop layers and supporting layers of the interconnects.

10. The structure according to claim 8, wherein the material of the interconnects is selected from the group consisting of Al interconnects, Cu interconnects and AlSiCu alloy interconnects.

11. The structure according to claim 9, wherein the material of the first spacers is silicon oxide.

12. The structure according to claim 9, wherein the material of the second spacers is selected from the group consisting of silicon nitride and silicon oxynitride.

13. The structure according to claim 9, wherein further comprising at least one anti-reflection layer formed on the top surface of the interconnects.

14. The structure according to claim 13, wherein the material of the anti-reflection layer is selected from the group consisting of Ti/TiN and SiON.
